(19) United States
(12) Patent Application Publication
(10) Pub. No.: US 2015/0340525 A1
(43) Pub. Date: Nov. 26, 2015

(54) METHOD FOR FORMING CHALCOGENIDE LAYERS

(71) Applicants: IMEC VZW, Leuven (BE); King Abdulaziz City for Science and Technology, Riyadh (SA); Universiteit Hasselt, Hasselt (BE)

(72) Inventor: Souhaib Oueslati, Tunis, TN (US)

(21) Appl. No.: 14/697,344

(22) Filed: Apr. 27, 2015

(30) Foreign Application Priority Data
May 20, 2014 (EP) 14168924.0

(51) Int. Cl. H01L 31/032; H01L 31/18

(52) U.S. Cl. CPC H01L 31/0322; H01L 31/18

(57) ABSTRACT

A method is provided for forming on a substrate a chalcogenide layer, the chalcogenide layer containing at least two metallic elements and containing Se. The method comprises depositing on the substrate a metallic layer containing the at least two metallic elements; and annealing the metallic layer in an environment comprising both a S-containing vapor such as H₂S vapor and a Se-containing vapor such as H₂Se vapor, thereby forming the chalcogenide layer. The annealing may for example be done at a temperature in the range between 450° C. and 550° C., resulting in a layer with good morphological quality and large grain size, the layer being free of S. A method of the various embodiments may for example be used for forming an absorber layer of a photovoltaic cell.

### CROSS-REFERENCE TO RELATED APPLICATION

Any and all priority claims identified in the Application Data Sheet, or any correction thereto, are hereby incorporated by reference under 37 CFR 1.57. This application claims the benefit of European Application No. EP 14168924.0, filed May 20, 2014. The aforementioned application is incorporated by reference herein in its entirety, and is hereby expressly made a part of this specification.

### FIELD

Methods for forming chalcogenide layers having a well-controlled composition are provided. Such chalcogenide layers may, for example, be used as an absorber layer in chalcogenide based photovoltaic cells.

### STATE OF THE ART

Chalcopyrite ternary thin layers, such as copper-indium-gallium-sulfoselenide (CuIn_{1-X}Ga_{X}(S,Se)₂) layers, and kesterite quaternary thin layers, such as copper-zinc-tin-sulfoselenide (Cu₂ZnSn(S,Se)₄) layers, generically referred to as CIGS layers and CZTS layers respectively, have become the subject of considerable interest and study for their use in semiconductor devices in recent years. These materials are also referred to as I-III-VI₂ and I₂-II-IV-VI₄ materials according to their constituent elemental groups. These materials are of particular interest for use as an absorber layer in photovoltaic devices.

For photovoltaic applications, a p-type CIGS or CZTS layer may be combined with a thin n-type semiconductor layer such as for example a CdS layer to form a p-n heterojunction CdS/CIGS or CdS/CZTS device.

A known method for forming a CIGS or CZTS layer on a substrate is based on the deposition of the metallic precursor metals on the substrate, thereby forming a metallic layer, followed by annealing in a chalcogen containing ambient to form the chalcogenide layer. Deposition of the metallic precursor metals may for example be done by co-evaporation or co-sputtering (or, alternatively, sequential sputtering) of the metallic precursor materials (I-III or elements) on the substrate at ambient temperature. The annealing may for example be done in a selenide vapor ambient. This process is known as a selenization process. During selenization, Se is incorporated into the metallic layer and a Se-containing chalcogenide layer is formed. As an alternative, the annealing may be done in a sulfide vapor environment. This process is known as a sulfurization process. During sulfurization, S is incorporated into the metallic layer and a S-containing chalcogenide layer is formed.

Because of the variety and complexity of the reactions taking place during the selenization process or during the sulfurization process, the composition and properties of the resulting chalcogenide layers are difficult to control. For example, during the selenization process (or alternatively: sulfurization process), metals may evaporate from the metallic layer, resulting in an uncontrolled composition of the chalcogenide layer. This makes the optimization of the initial metallic layer composition difficult and causes the metal ratio after selenization or sulfurization to be pseudo-random.

When using such a chalcogenide layer with an uncontrolled composition as an absorber layer in a photovoltaic cell, this results in a low or unpredictable photovoltaic cell efficiency, and in some cases it may result in a non-functional photovoltaic cell.

### SUMMARY

A method for forming chalcogenide layers is provided wherein the composition can be well controlled. More in particular, the various embodiments aim to provide a method for forming Se-containing chalcogenide layers having a well-controlled composition.

Provided is a method for forming chalcogenide layers with a large average grain size, e.g. an average grain size that is larger than the average grain size of chalcogenide layers formed using known methods. Using a method according to the various embodiments, chalcogenide layers having an average grain size larger than 1 micrometer, for example larger than 3 micrometer, or larger than 5 micrometer may be formed.

A method is provided for forming on a substrate a chalcogenide layer, the chalcogenide layer containing at least two different metallic elements and containing Se, wherein the method comprises: depositing on the substrate a metallic layer containing the at least two metallic elements; and annealing the metallic layer in an environment comprising both a S-containing vapor and a Se-containing vapor, thereby forming the chalcogenide layer.

In various embodiments, the S-containing vapor may for example be a H₂S vapor and/or the Se-containing vapor may for example be a H₂Se vapor, the various embodiments not being limited thereto.

In various embodiments a vapor pressure of the S-containing vapor may be higher than a vapor pressure of the Se-containing vapor.

In the context of the various embodiments, a metallic layer is a layer containing only metallic elements. In the context of the various embodiments, a metallic layer does not contain elements other than metallic elements, e.g. it does not contain a chalcogen element.

It was surprisingly found that a chalcogenide layer formed according to a method of the various embodiments has a well-controlled composition. It was surprisingly found that the amount of metallic elements lost (e.g. by evaporation) during the annealing or selenization process is lower as compared to a method wherein the annealing or selenization is done in the absence of a S-containing vapor, e.g. in the absence of H₂S.

It was surprisingly found that a chalcogenide layer formed according to a method of the various embodiments is free of sulfur, i.e. the chalcogenide layer does not contain any sulfur.

In a method according to the various embodiments, the annealing may be performed at a temperature in the range between 450° C. and 550° C. It is an advantage of a method of the various embodiments that the annealing (selenization process) can be done at a temperature that is higher than in prior art selenization processes, without the risk of segregation of chalcogenide grains and without the risk of evaporation of metallic elements from the metallic layer.

It is an advantage of using a higher annealing temperature that larger grains may be obtained. When used as an absorber layer in a photovoltaic cell, a chalcogenide layer with larger grain size may result in a larger cell efficiency.

Depositing the metallic layer may comprise sequentially depositing the at least two metallic elements. Alternatively, depositing the metallic layer may comprise simultaneously depositing (co-depositing) the at least two metallic elements.

In various embodiments, the metallic layer may for example contain three different metallic elements. For example, when using a method of the various embodiments for forming a CIGSe chalcogenide layer, the metallic layer may contain Cu, In and Ga. For example, when using a method of the various embodiments for forming a CZTSe chalcogenide layer, the metallic layer may contain Cu, Zn and Sn.

A method according to the various embodiments may advantageously be used for forming a chalcogenide semiconductor layer, such as for example an absorber layer of a photovoltaic cell.

It is an advantage of a method according to the various embodiments that it allows forming Se-containing chalcogenide layers with a well-controlled composition in a reproducible way.

It is an advantage of a method according to the various embodiments that it results in chalcogenide layers of good morphological quality and with a relatively large average grain size. For example, the average grain size may be larger than 3 micrometer, e.g. larger than 5 micrometer.

Certain objects and advantages of various inventive aspects have been described herein above. Of course, it is to be understood that not necessarily all such objects or advantages may be achieved in accordance with any particular embodiment herein. Thus, for example, those skilled in the art will recognize that the embodiments may be carried out in a manner that achieves or optimizes one advantage or group of advantages as taught herein without necessarily achieving other objects or advantages as may be taught or suggested herein. Further, it is understood that this summary is merely an example and is not intended to limit the scope of the invention. The invention, both as to organization and method of operation, together with features and advantages thereof, may best be understood by reference to the following detailed description.

### BRIEF DESCRIPTION OF THE FIGURES

FIG. 1 illustrates process steps of a method according to an embodiment of the various embodiments.

Any reference signs in the claims shall not be construed as limiting the scope of the various embodiments.

In the different drawings, the same reference signs refer to the same or analogous elements.

The drawings are only schematic and are non-limiting. In the drawings, the size of some of the elements may be exaggerated and not drawn on scale for illustrative purposes.

### DETAILED DESCRIPTION

In the following detailed description, numerous specific details are set forth in order to provide a thorough understanding of the invention and how it may be practiced in particular embodiments. However, it will be understood that the various embodiments may be practiced without these specific details. In other instances, well-known methods, procedures and techniques have not been described in detail, so as not to obscure the various embodiments.

The various embodiments will be described with respect to particular embodiments, but are not limited thereto but only by the claims.

Furthermore, the terms first, second, third and the like in the description and in the claims, are used for distinguishing between similar elements and not necessarily for describing a sequential or chronological order. The terms are interchangeable under appropriate circumstances and the embodiments can operate in other sequences than described or illustrated herein.

Moreover, the terms top, bottom, over, under and the like in the description and the claims are used for descriptive purposes and not necessarily for describing relative positions. It is to be understood that the terms so used are interchangeable under appropriate circumstances and that the embodiments described herein are capable of operation in other orientations than described or illustrated herein.

The term “comprising”, used in the claims, should not be interpreted as being restricted to the means listed thereafter; it does not exclude other elements or steps. It needs to be interpreted as specifying the presence of the stated features, integers, steps or components as referred to, but does not preclude the presence or addition of one or more other features, integers, steps or components, or groups thereof. Thus, the scope of the expression “a device comprising means A and B” should not be limited to devices consisting only of components A and B.

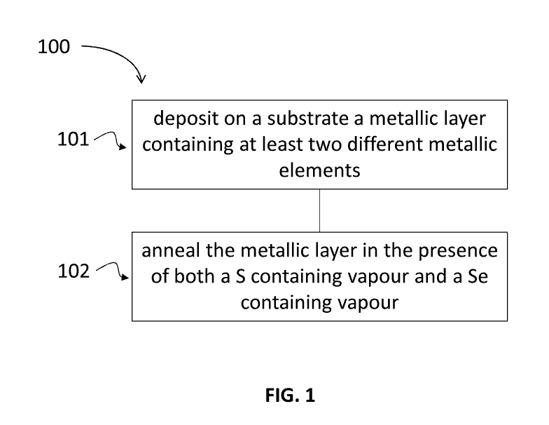

A method for forming on a substrate a chalcogenide layer with a well-controlled composition is provided, the chalcogenide layer comprising at least two different metallic elements and Se. FIG. 1 illustrates process steps of a method 100 according to an embodiment of the various embodiments. The method comprises, at step 101, depositing on the substrate a metallic layer containing the at least two different metallic elements and, at step 102, annealing the metallic layer in an environment comprising both a S-containing vapor, such as for example a H₂S vapor, and a Se-containing vapor, such as for example a H₂Se vapor, thereby forming the chalcogenide layer. During the annealing step, the vapor pressure of the S-containing vapor is preferably higher than the vapor pressure of the Se-containing vapor.

In embodiments, the annealing 102 may for example be performed at a temperature in the range between 450° C. and 550° C., such as for example in the range between 460° C. and 520° C., the various embodiments not being limited thereto. The annealing may for example be performed for 5 minutes to 1 hour, for example 10 minutes to 30 minutes, for example about 15 minutes.

It was surprisingly found that a method of the various embodiments leads to chalcogenide layers with good morphological quality, the chalcogenide layers having a reduced number of voids and a reduced amount of secondary phases as compared to chalcogenide layers formed by known methods. Such chalcogenide layers may advantageously be used as an absorber layer in a photovoltaic cell. As compared to prior art methods, less metal is lost (e.g. by evaporation) from the metallic layer during annealing, even at an annealing temperature higher than 500° C.

In embodiments, depositing 101 the metallic layer may comprise co-depositing, e.g. co-sputtering, the at least two metallic elements. In embodiments, depositing 101 the metallic layer may comprise sequentially depositing, e.g. sequentially sputtering, the at least two metallic elements.

In various embodiments, a H₂S flow rate in the range between 20 sccm and 200 sccm may for example be used, the various embodiments not being limited thereto. In various embodiments, a H₂Se flow rate in the range between 20 sccm and 200 sccm may for example be used, the various embodiments not being limited thereto.

CZTSe layers were fabricated in accordance with an embodiment of a method. Thin layers of Sn, Zn and Cu were sequentially sputtered on a substrate. Afterwards the samples were annealed in an environment containing H₂Se vapor and H₂S vapor, at temperatures in the range between 460° C. and 520° C. for 15 minutes. In the experiments different H₂Se/H₂S ratios, ranging from 20 sscm H₂Se/180 sccm H₂S to 180 sccm H₂Se/20 sccm H₂S, were used. The total flow rate (H₂Se+H₂S) was 200 sccm in all experiments. For all H₂Se/H₂S ratios used, Se-containing layers free of S were obtained with a well-controlled composition and with a large grain size.

The CZTse layers formed show average grain sizes in the range between 3 micrometer and 5 micrometer. The CZTSe layers also have good physical properties (e.g. band gap, crystal structure), as determined by photoluminescence and X-Ray diffraction. Energy dispersive X-ray analysis EDX showed that the Zn/Sn ratio was almost constant with increasing annealing temperature, which is not the case when using prior art selenization methods, i.e. in the absence of a S-containing vapor such as H₂S.

When a prior art selenization process is used, i.e. when the selenization process is done in the absence of a S-containing vapor such as H₂S, increasing the annealing temperature to 450° C. or higher leads to an exponential increase of the Zn/Sn ratio in the chalcogenide layer. This increase is caused by evaporation of Sn from the metallic layer. It was surprisingly found that this is not the case when introducing a S-containing vapor such as H₂S in the selenization chamber, in accordance with the various embodiments.

In various embodiments, the stoichiometric composition of the chalcogenide layer after the annealing is substantially identical to that determined by the composition of the as-deposited metallic layer and its reaction with selenium.

The chalcogenide layer formed according to a method of the various embodiments does not contain sulfur. This was shown based on photoluminescence measurement at room temperature, XRD (X-Ray Diffraction) and EDX (Energy-Dispersive X-ray spectroscopy) measurements.

A chalcogenide layer containing sulfur and selenium may be obtained by performing a sulfurization process, after forming the Se-containing chalcogenide layer according to the various embodiments. The sulfurization process may for example comprise annealing in a H₂S environment, not containing Se.

After deposition of the chalcogenide absorption layer, a known photovoltaic cell processing method may be applied, for example including KCN etching, buffer layer deposition and window layer deposition.

The foregoing description details certain embodiments of the invention. It will be appreciated, however, that no matter how detailed the foregoing appears in text, the invention may be practiced in many ways. It should be noted that the use of particular terminology when describing certain features or aspects should not be taken to imply that the terminology is being re-defined herein to be restricted to including any specific characteristics of the features or aspects of the invention with which that terminology is associated.

While the above detailed description has shown, described, and pointed out novel features of the invention as applied to various embodiments, it will be understood that various omissions, substitutions, and changes in the form and details of the device or process illustrated may be made by those skilled in the technology without departing from the invention.

All references cited herein are incorporated herein by reference in their entirety. To the extent publications and patents or patent applications incorporated by reference contradict the disclosure contained in the specification, the specification is intended to supersede and/or take precedence over any such contradictory material.

Unless otherwise defined, all terms (including technical and scientific terms) are to be given their ordinary and customary meaning to a person of ordinary skill in the art, and are not to be limited to a special or customized meaning unless expressly so defined herein. It should be noted that the use of particular terminology when describing certain features or aspects of the disclosure should not be taken to imply that the terminology is being re-defined herein to be restricted to include any specific characteristics of the features or aspects of the disclosure with which that terminology is associated. Terms and phrases used in this application, and variations thereof, especially in the appended claims, unless otherwise expressly stated, should be construed as open ended as opposed to limiting. As examples of the foregoing, the term ‘including’ should be read to mean ‘including, without limitation,’ ‘including but not limited to,’ or the like; the term ‘comprising’ as used herein is synonymous with ‘including,’ ‘containing,’ or ‘characterized by,’ and is inclusive or open-ended and does not exclude additional, unrecited elements or method steps; the term ‘having’ should be interpreted as ‘having at least;’ the term ‘includes’ should be interpreted as ‘includes but is not limited to;’ the term ‘example’ is used to provide exemplary instances of the item in discussion, not an exhaustive or limiting list thereof; adjectives such as ‘known’, ‘normal’, ‘standard’, and terms of similar meaning should not be construed as limiting the item described to a given time period or to an item available as of a given time, but instead should be read to encompass known, normal, or standard technologies that may be available or known now or at any time in the future; and use of terms like ‘preferably,’ ‘preferred,’ ‘desired,’ or ‘desirable,’ and words of similar meaning should not be understood as implying that certain features are critical, essential, or even important to the structure or function of the invention, but instead as merely intended to highlight alternative or additional features that may or may not be utilized in a particular embodiment of the invention. Likewise, a group of items linked with the conjunction ‘and’ should not be read as requiring that each and every one of those items be present in the grouping, but rather should be read as ‘and/or’ unless expressly stated otherwise. Similarly, a group of items linked with the conjunction ‘or’ should not be read as requiring mutual exclusivity among that group, but rather should be read as ‘and/or’ unless expressly stated otherwise.

Where a range of values is provided, it is understood that the upper and lower limit, and each intervening value between the upper and lower limit of the range is encompassed within the embodiments.

With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity. The indefinite article “a” or “an” does not exclude a plurality. A single processor or other unit may fulfill the functions of several items recited in the claims. The mere fact that certain measures are recited in mutually different dependent claims does not indicate that a combination of these measures cannot be used to advantage. Any reference signs in the claims should not be construed as limiting the scope.

It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to embodiments containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

All numbers expressing quantities of ingredients, reaction conditions, and so forth used in the specification are to be understood as being modified in all instances by the term ‘about.’ Accordingly, unless indicated to the contrary, the numerical parameters set forth herein are approximations that may vary depending upon the desired properties sought to be obtained. At the very least, and not as an attempt to limit the application of the doctrine of equivalents to the scope of any claims in any application claiming priority to the present application, each numerical parameter should be construed in light of the number of significant digits and ordinary rounding approaches.

Furthermore, although the foregoing has been described in some detail by way of illustrations and examples for purposes of clarity and understanding, it is apparent to those skilled in the art that certain changes and modifications may be practiced. Therefore, the description and examples should not be construed as limiting the scope of the invention to the specific embodiments and examples described herein, but rather to also cover all modification and alternatives coming with the true scope and spirit of the invention.

What is claimed is:

1. A method for forming a chalcogenide layer on a substrate, comprising:
depositing a metallic layer on a substrate, the metallic layer containing at least two different metallic elements; and
annealing the metallic layer in an environment comprising both a S-containing vapor and a Se-containing vapor, whereby a chalcogenide layer is formed.

2. The method of claim 1, wherein the S-containing vapor is a H₂S-containing vapor.

3. The method of claim 1, wherein the Se-containing vapor is a H₂Se-containing vapor.

4. The method of claim 1, wherein a vapor pressure of the S-containing vapor is higher than a vapor pressure of the Se-containing vapor.

5. The method of claim 1, wherein annealing comprises annealing at a temperature of from 450° C. to 550° C.

6. The method of claim 1, wherein depositing the metallic layer comprises sequentially depositing the at least two different metallic elements.

7. The method of claim 1, wherein depositing the metallic layer comprises simultaneously depositing the at least two different metallic elements.

8. The method of claim 1, wherein the metallic layer contains three different metallic elements.

9. The method of claim 8, wherein the metallic layer contains Cu, In and Ga.

10. The method of claim 8, wherein the metallic layer contains Cu, Zn and Sn.

11. The method of claim 1, further comprising:
fabricating a photovoltaic cell containing the chalcogenide layer, wherein the chalcogenide layer is a chalcogenide absorber layer.
